(19) United States
(12) Patent Application Publication
(10) Pub. No.: US 2023/0020885 A1
(43) Pub. Date: Jan. 19, 2023

(54) AUTOMATIC CONVERSION OF 2D SCHEMATICS TO 3D MODELS

(71) Applicant: Ganesh Balasubramanian, Chennai (IN)

(72) Inventor: Ganesh Balasubramanian, Chennai (IN)

(21) Appl. No.: 17/810,442

(22) Filed: Jul. 1, 2022

Related U.S. Application Data
(60) Provisional application No. 63/202,981, filed on Jul. 2, 2021.

(51) Int. Cl. G06F 30/13; G06F 30/23; G06F 30/17

(52) U.S. Cl. CPC G06F 30/13; G06F 30/23; G06F 30/17

(57) ABSTRACT

A method for dynamically and automatically creating a three-dimensional (3D) model utilizing one or more two dimensional (2D) schematics corresponding to a project is disclosed. The method includes receiving the one or more two-dimensional (2D) schematics onto a first server application, utilizing a Building Information Modeling (BIM) 3D modeling program for the purpose of extracting location and/or position data for the project from the corresponding two-dimensional schematics, determination and classification of various objects from the corresponding 2D schematics, extracting a planar shape information for each of the objects wherein each of the planar shape information is utilized to determine a corresponding 3D shape/orientation of each of the objects, and combining the position data, the classification data and the orientation data into an extracted information file which is then converted to develop a 3D model corresponding to the 2D schematics.

### CROSS-REFERENCE TO RELATED APPLICATION

The present application claims priority to U.S. provisional application Ser. No. 63/202,981, filed Jul. 2, 2021, the contents of which are hereby incorporated by reference in their entirety.

### TECHNICAL FIELD

The present disclosure generally relates to computer aided designing techniques and more particularly relates to a method and system for creating a three-dimensional Model from a set of two-dimensional Schematics without manual human intervention.

### BACKGROUND

In today's modeling environment, particularly in construction industry, there has been an increased demand of three-dimensional models rather than previously utilized two-dimensional schematics and sketches. Such two-dimensional models are used as the foundation for designers to bring designs into reality in the form of detailed construction drawings, images, and renderings so as to clearly represent projects to other designers, builders, and clients.

However, most of the product or industrial designers create renderings in the form of two-dimensional vector-based drawings or models. While such CAD drawings demonstrate the size, appearance, texture and material of products/building/components that have yet to be manufactured, there has been a complicated process, which needs to be followed to prepare a 3-dimensional model from such two-dimensional schematics. Conventional 3D modeling tools require fairly high precision, detail and attention to generate shapes. Further, such a process requires a lot of human effort and time, and therefore is not preferred. For example, large scale projects like airports, hospitals, infrastructure projects require spending substantial amount of time in conversion from two dimensional schematics to 3D model. Accordingly, there has been a rapid increase in demand for the products/solutions that may be helpful in converting the two dimensional schematics into 3 dimensional models.

Current solutions for conversion of two-dimensional images to stereoscopic images fall into two broad categories. In some developments, there have been systems which convert two-dimensional images into three-dimensional images wherein the two-dimensional images have no associated depth maps or other depth information. Systems in this category may be automated to provide depth information based on colors or areas of the picture, however, these systems have had limited success. Other systems in this category require a considerable amount of manual labor for highly accurate results. Therefore, expense and time of the conversion process to achieve an accurate three-dimensional model is increased. Further, this limits the usefulness of creating 3D models from 2D geometry, because extra steps are required to add dimensional values manually each time editing has to be performed on the model to make a revision.

Other systems include various Building Information Modeling (BIM) processes adapted to the generate and/or manage digital representations of physical and functional characteristics of physical spaces. However, such modeling programs have various shortcomings such as these are trained with predefined shapes/structures/elements and therefore, may not be easily extended for new shapes/designs/structural components. Additionally, such new 3D models are usable on only proprietary 3D modeling program and are not in a format that is directly compatible with a second 3D modeling view/edit programs.

Accordingly, it is desirable to provide a system and method that creates an accurately visualized three-dimensional model by using a set of two-dimensional schematics as input while reducing requirement of human intervention substantially. Further, such three-dimensional program while still being extendable to new shapes/elements/structures etc. must be compatible to generally available CAD programs known in the art so that it can be utilized with the existing infrastructure without requiring any changes therein.

### SUMMARY

In one aspect of the present subject matter, a method for dynamically and automatically creating a three-dimensional (3D) model utilizing one or more two dimensional (2D) schematics/drawings corresponding to a project, is disclosed. The method includes receiving the one or more two-dimensional (2D) Schematics onto a first application server. The method further includes utilizing a Building Information Modeling (BIM) 3D modeling program for the purpose of extracting location and/or position data for the project from the corresponding two-dimensional drawings/schematics. The method furthermore includes determination and classification of various elements/objects from the corresponding two-dimensional drawings/schematics. Furthermore, the method provides extracting a planar shape information for each of the elements/objects wherein each of the planar shape information is utilized to determine a corresponding three-dimensional shape/orientation of each of the elements/objects. Thereafter, the method includes combining the position data, the classification data and the orientation data, and thereafter encrypting into a single extracted information file. The extracted information file is then utilized to develop a three-dimensional model corresponding to the two-dimensional schematics.

In a preferred embodiment, the application server includes an object library comprising a plurality of extracted information files along with corresponding three-dimensional model.

In an embodiment, the BIM program includes a three-dimensional object library application comprising one or more programming instructions having definitions/details for performing the steps of extraction and classification of elements/objects from the two-dimensional schematics, utilizing the object library.

Further preferably, the method includes updation and/or enhancement of the library application by allowing the addition of new three-dimensional object models including corresponding definitions received from the current three-dimensional modeling process as well as from one or more second application server connected to the first application server, within the object library.

In yet another embodiment, the two-dimensional schematics include a combination of a text data, a plurality of line drawings and a project information data therewithin.

Preferably, the location and/or position data is extracted from the project information data provided within the two-dimensional schematics.

Further preferably, the determination of various elements and/or objects is performed by extracting the corresponding details from the text data provided within the two-dimensional schematics.

In yet another embodiment, the three dimensional shapes and/or orientation is extracted from the line drawings provided within the two-dimensional schematics.

In yet another embodiment, the method includes additional steps of extracting the three dimensional shapes and/or orientations from the line drawings, the steps including extraction of planar shapes from the line drawings using a first pattern recognition sub-program followed by determination of three-dimensional orientation for the corresponding planar shapes using a second pattern recognition sub-program applied onto an output of the first pattern recognition sub-program.

In yet another embodiment, the method further includes determining dimensions and/or any other similar attribute from the two-dimensional schematics utilizing a dimensioning sub-program of the BIM Program.

Preferably, the project corresponding to the two dimensional schematics represents an architectural design such as including but not limited to a housing society, a multi-floor building, museum, airports, hospitals, infrastructure projects and the like.

Further preferably, the elements and/or objects of the two dimensional schematics may be one or more of but not limited to building components such as architectural components, structural components, mechanical/electrical/plumbing/firefighting components, and/or interior components.

In an embodiment, the two-dimensional schematics may be in the form of Computer Aided Design.

In an embodiment, the two-dimensional schematics may be in the form of hand drawing sketches, paint based drawing, and any other suitable format conventionally known in the art

In another aspect, a system for dynamically and automatically creating a three-dimensional (3D) model utilizing one or more two dimensional (2D) schematics/drawings corresponding to a project, is disclosed. The system includes a computing unit having a processor and memory configured to execute one or more programming instructions embodied thereon. The system further includes a first application server having an information receiving component adapted to receive two-dimensional schematics from a user. The received two-dimensional schematics pertains to at least one project associated to said two-dimensional schematics.

The first application server includes a BIM modeling Program having an application connected to one or more data sources defining a CAD Object Library consisting of a plurality of definition/models for appropriately extracting three-dimensional model information from the two-dimensional shapes and/or orientation and/or information. The library application is further adapted to store the extracted information as an encrypted extracted information file within the CAD Object Library. The BIM Program further includes a three-dimensional model creating module adapted to utilize the plurality of three-dimensional model information including project location information, elements/objects classification and elements shapes and/or orientation and combine them to create a three-dimensional model corresponding to the input set of two-dimensional schematics. Particularly, the 3D model creating module is configured to process one or more programming instructions embodied onto the memory of the application server, to convert the extracted information file in accordance with the BIM Model, to output a three-dimensional model. The system further includes a visualization generation component that dynamically generates a three-dimensional model visualization of the project on to an output screen.

Preferably, the CAD Library is an additionally connected to and adapted to receive updated 3D modeling definition and/or corresponding extracted information files from one or more second application server employing one or more second BIM model through one or more communication means.

Additionally, the system includes an AI component adapted to improvise the extraction operation of the BIM model in accordance with the enhanced CAD library such that a learning is developed from various 3D modeling operations performed across any of the connected application server so as to improvise the accuracy of the 3-dimensional model developed by the BIM 3D Model. The accuracy level of up to 99% is achieved.

Numerous additional features, embodiments, and benefits of the methods and apparatus of the present invention are discussed below in the detailed description which follows.

The details of one or more implementations are set forth in the accompanying drawings and the description below. Other aspects, features and advantages of the subject matter disclosed herein will be apparent from the description, the drawings, and the claims.

### SHORT DESCRIPTION OF DRAWINGS

The accompanying drawings illustrate various embodiments of systems, methods, and other aspects of the disclosure. Any person having ordinary skill in the art will appreciate that the illustrated element boundaries (e.g., boxes, groups of boxes, or other shapes) in the figures represent one example of the boundaries. It may be that in some examples, one element may be designed as multiple elements or that multiple elements may be designed as one element. In some examples, an element shown as an internal component of one element may be implemented as an external component in another, and vice versa. Furthermore, elements may not be drawn to scale.

FIG. 1 illustrates a system block diagram of a system for converting two-dimensional schematics into a three-dimensional model according to an embodiment of the present subject matter.

FIGS. 2a through 2b illustrate a flow chart depicting a method of converting two-dimensional schematics into a three-dimensional model according to an embodiment the present subject matter.

FIG. 4a through 4c illustrate an exemplary 2D to 3D conversion of various structural components in accordance with an embodiment of the present subject matter.

Various embodiments will hereinafter be described in accordance with the appended drawings, which are provided to illustrate, and not to limit the scope in any manner, wherein like designations denote similar elements.

### DETAILED DESCRIPTION

The present subject matter is best understood with reference to the detailed figures and description set forth herein. Various embodiments are discussed below with reference to the figures. However, those skilled in the art will readily appreciate that the detailed descriptions given herein with respect to the figures are simply for explanatory purposes as the methods and systems may extend beyond the described embodiments. For example, the teachings presented and the needs of a particular application may yield multiple alternate and suitable approaches to implement the functionality of any detail described herein. Therefore, any approach may extend beyond the particular implementation choices in the following embodiments described and shown. The present application discloses a system for converting a set of one or more two-dimensional schematics/drawings, associated to a project, into a three-dimensional model visualizing the project similar to what it would look like when constructed completely, without much human manual intervention. The system is further adapted to auto update itself with various elements/objects/3D models including their shapes, orientations for various 2D schematics such as lines, shapes, texts etc., in a way that there is no dependencies between various objects/elements and the system, eliminating the subsequent issues. The system is generally provided in the form of a web application and/or automated service, that could be accessed through internet/website. However, in another embodiment, the system may be in form of a graphically visualized client application that could be accessed with a computing device.

Particularly, the system of the present embodiment is adapted to identify various elements/objects including their attributes, project information including location and/GPS data and any other factors that is associated to the project that needs to be modeled from the two dimensional schematics, such as including but not limited to architectural components, structural components, Mechanical/electrical/plumbing components, interior components, and the like, that may be modeled and then combined for the purpose of generating a three dimensional visualizable model of the project. It is to be understood that unless otherwise indicated, this invention need not be limited to applications for construction projects. As one of ordinary skill in the art would appreciate, variations of the invention may be applied to other products/projects such as in field of industrial designs, medical equipment, entertainment industry, including any other field of daily life where a three-dimensional visualization is required. Moreover, it should be understood that embodiments of the present invention may be applied in combination with various computer aided design tools known in the art. It must also be noted that, as used in this specification and the appended claims, the singular forms “a,” “an” and “the” include plural referents unless the context clearly dictates otherwise. Thus, for example, the term “a drawing” is intended to mean a single drawing or a combination of drawings, “an application” is intended to mean one or more applications for a same purpose, or a combination of applications for performing different program executions.

References to “one embodiment,” “an embodiment.” “at least one embodiment,” “one example,” “an example,” “for example,” and so on, indicate that the embodiment(s) or example(s) so described may include a particular feature, structure, characteristic, property, element, or limitation, but that not every embodiment or example necessarily includes that particular feature, structure, characteristic, property, element or limitation. Furthermore, repeated use of the phrase “in an embodiment” does not necessarily refer to the same embodiment.

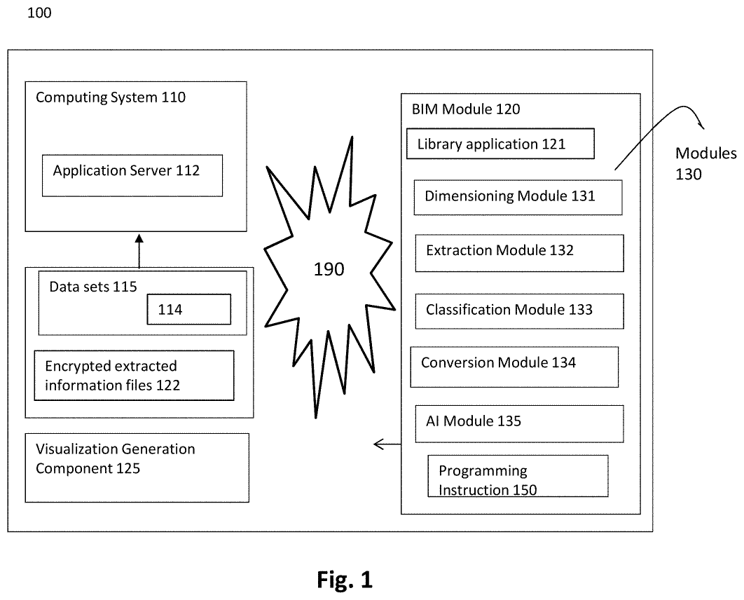

FIG. 1 illustrates a system block diagram of a system for automatic conversion of 2D schematics to 3D models according to an embodiment of the present invention. The system 100 includes a computing unit 110 connected to an application server 112 that is adapted to receive data sets 114 from a plurality of data sources 115 of a plurality of other application servers. The plurality of data sources 115 includes a plurality of data sets pertaining to factors relevant to determine/identify/classify elements and/or objects in a two dimensional schematic and corresponding three dimensional alternates for them. Particularly, the plurality of data sources 115 include one or more CAD Libraries storing data related to one or more elements/objects/components present within the two dimensional schematics and corresponding three dimensional orientations/shapes/models that may be utilized for the purpose of converting two dimensional schematics into three dimensional models in an embodiment.

The system 100 further includes a BIM three-dimensional model 120 adapted to receive one or more sets of two-dimensional schematics associated to said project through the application server 112. Particularly, the BIM three-dimensional model 120 is configured to processes the received two dimensional schematics, in accordance with one or more programming instructions 150 so to produce a three-dimensional model [not shown] related to the project, using the data sets 115 including the CAD Libraries.

In an embodiment of the present invention, the BIM three dimensional model 120 may recognize the two dimensional schematics, and extract position data, and/or elements/object data and classification thereof, along with corresponding three dimensional shape and/or orientation based on the data sets 115, and combine them in accordance to programming instructions 150 so as to produce the three dimensional model thereof based on known, anticipatory, historical, and/or premonitory data related to various three-dimensional model(s) produced across the plurality of application servers.

In some embodiments, the BIM three dimensional model 120 includes a library application 121, that is adapted to first recognize the two dimensional schematics, and extract position data, and/or elements/object data and classification thereof, along with corresponding three dimensional shape and/or orientation based on the CAD Object Libraries present within the data sets 115 and then combine them together in an encrypted information file 122 which is then utilized by the BIM model 120 to form the three-dimensional model corresponding thereto.

The encrypted extracted information files 122 includes information extracted from the two-dimensional schematics in software readable format such as for example, an XML format. Further, the encryption may be done using any conventional and suitable known encryption mechanism to safeguard the information stored therewithin. In some embodiments, the encrypted extracted information files 122 are stored within the CAD object Libraries of the data sets 115. In some embodiments, the extracted information files 122 are stored as a predetermined file format, for example, in a preferred example, as a .CAP file Format. The extracted information files 122 may be accessed and/or opened using any conventionally available tools such as including but not limited to Autocad™, Revit™, SketchUp™, ZWCAD™, DraftSight™, NanoCAD™, BricsCAD™, LibreCAD™, CMS IntelliCAD™. Such tools should be configured to decrypt the encrypted extracted information file 122 and therefore should be upgraded before being able to access the content of such extracted information files 122.

In certain embodiments, the extraction and determination may be based on any predetermined extraction mechanism known in the art, and in accordance with the programming instructions 150. Further, the programming instructions 150 may be configured to learn and improvise in accordance with AI based models such as heuristic models (e.g., neural networks, fuzzy logic models, machine learning, expert system models, state vector machine models). Particularly, the machine learning concept is employed to train the applications to understand 2D elements, map the respective 2D elements to 3D objects which thereby corrects the 2D schematics to 3D models quickly. For example, manual 2D to 3D conversion for a 1000 sq. ft home, might take 8 to 10 hours to create 3D model. However, automated conversion of 2D to 3D for same home might take 1 to 2 hours to create 3D model in an embodiment.

The system 100 further includes a visualization generation component 125 to generate an interactive visualization of the three dimensional model generated by the BIM 3D module 120.

In an embodiment, the BIM 3D module 120 includes a plurality of sub modules 130, each adapted to impart a predetermined functionality. For example, in some embodiments, the sub module 130 includes dimensioning module 131, an extraction module 132, a classification module 133, a conversion module 134, and an AI module 135.

Each of the sub-module 130 is associated to a predetermined programming instruction set, embodied onto the memory and adapted to generate a score specific to the predetermined perspective thereof.

For example, the dimensioning module 131 is configured to automatically determine various dimensions related attributes for various elements/components determined within the project.

In an embodiment, the extraction module 132 is associated to another set of programming instruction and is adapted to generate an extraction of information from various kind of data within the two-dimensional schematics for example, position data from project information, elements/objects information from the text information, and orientation/shapes from the line drawings from within the two dimensional schematics.

The classification module 133 is associated to yet another set of programming instructions 150 and is adapted to generate a classification of various elements/objects determined by the extraction module 132. In an embodiment, the classification is performed on the kind of components such as including but not limited to architectural components, structural components, the Mechanical/electrical/plumbing/firefighting components, and the interior components.

Similarly, the conversion module 134 using yet another set of programming instructions 150, is adapted to convert various elements/objects/components disclosed and extracted from the two dimensional schematics is converted to corresponding three-dimensional models/objects having corresponding shapes/orientations using the CAD Library 115. In the embodiments, where the BIM model 120 includes library application 121, the conversion module is adapted to convert the extracted information files 122 to a corresponding three-dimensional model.

Furthermore, the AI module 135 is adapted to consider all the other sub-modules 130, and in certain instances, the library application 121, using yet another set of programming instructions 150 to combine all the elements/objects/components, and produce the three dimensional model of the project. Moreover, the AI module 135 is further adapted to improvise the set of programming instructions 150, in accordance to updated data set 115 received from plurality of other data sources 114.

Accordingly, the programming instructions 150 of each of the sub-module 130 is specifically updated in accordance with 3 dimensional model created by a wide variety of user groups (such as designers, customers, structure engineers and logistic engineers, manufacturers, construction companies) so as to constantly upgrade the model 120 to increase the capability and ability of the system 100.

Examples of architectural elements/components include components that generally define an architecture of a building including but is not limited to Walls, Doors, Windows, Partition walls, Flooring, Ceiling, Skirting, Stairs, Railing and the like.

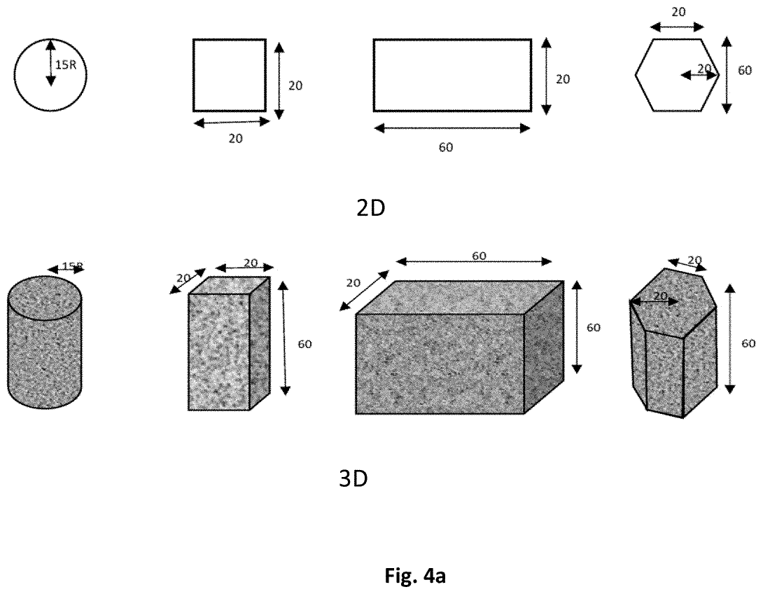

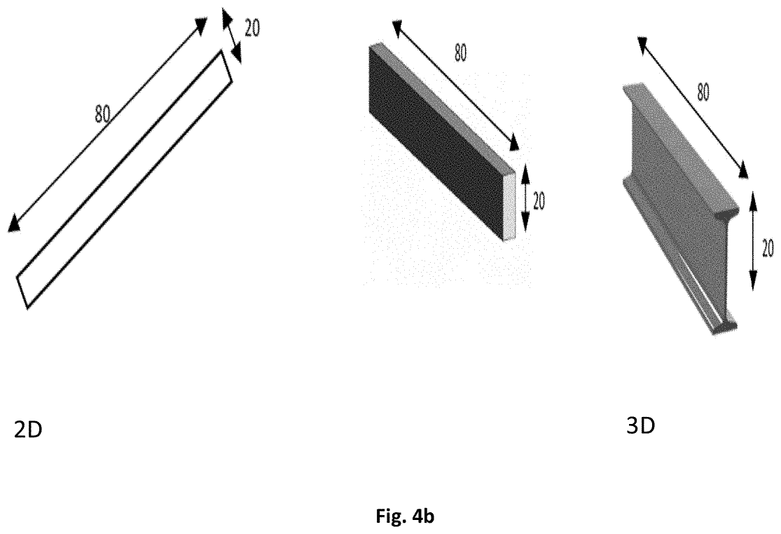

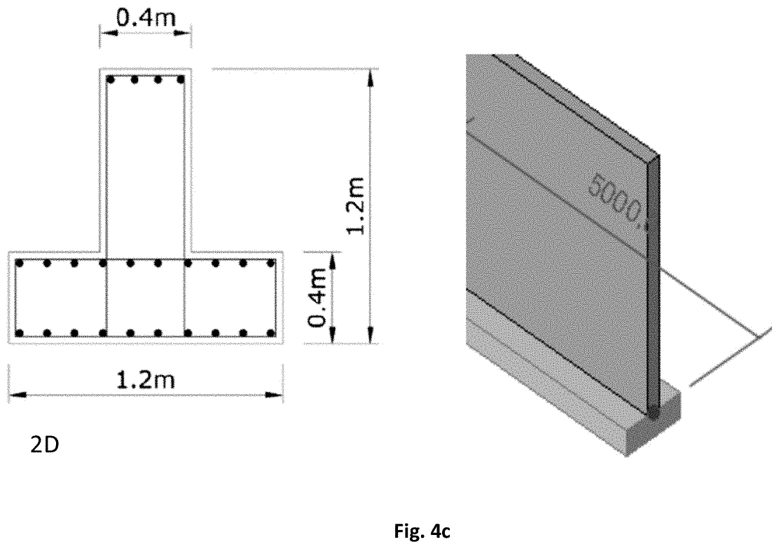

Examples of structural elements/components include components that generally define structure of a building including but is not limited to Columns, beams, Slabs, flat, Foundations, Slabs, Core walls and the like, as illustrated in FIG. 4a through FIG. 4c.

Examples of MEP components include components that generally define utility components of a building including but is not limited to ducts, Cables, trays, lightings, power points, Power sockets, Firefighting Cables, IT infrastructure such as firewall/cyber security assurance systems and other building components such as Utilities (Water, Power, Gas), Smart Grids, Transportation and the like.

Examples of interior components include components that generally define interior defining components of a building including but is not limited to sofa, beds, tables, couches, side tables, and the like.

In addition to above disclosed components, the elements/objects further include all other support elements or objects that are required for designing with in Construction Engineering projects and are known to a person skilled in the art without deviating from the scope of invention.

The system 100 and/or the computing unit 110 including the first and the second application servers, is intended to represent various forms of mobile devices, such as personal digital assistants, cellular telephones, smart phones, and other similar computing units. The components shown here, their connections and relationships, and their functions, are meant to be exemplary only, and are not meant to limit implementations described and/or claimed in this document.

In a preferred embodiment, the computing unit 110 includes a processor 161, memory 162, a storage device 163, a high-speed interface connecting to memory and high-speed expansion ports, and a low speed interface connecting to low speed bus, and one or more input/output (I/O) devices 164. Each of the components 161, 162, 163, 164, 165 are interconnected using various busses, and may be mounted on a common motherboard or in other manners as appropriate. The processor 161 can process the programming instructions 150 for execution within the system 100. In a preferred embodiment, the programming instructions 150 may be stored in the memory 162 or on the storage device 163 to display graphical information for a GUI on an external input/output device 164, such as display coupled to high speed interface. In other implementations, multiple processors and/or multiple busses may be used, as appropriate, along with multiple memories and types of memory.

In an embodiment of the present invention, the BIM 3D Model is connected with one or more of plurality of data sources 115 through a communication medium 190 such as a wireless communication connection, so as to receive data-sets 114 information through a wireless transceiver module 166. However, in other embodiments, the data receiving component 112 may use the input/output device 164 to receive data-sets 114 input by a user group handling the system 100. In yet other embodiment, the data receiving component 112 may include various application programming interface (API) connected to the data sources 115 so as to receive data-sets 114 there from in a format acceptable by the source API and readable by the computing unit 110.

The data receiving component 112 is connected with a central processor 161 so as to send the collected data-sets 114 to the central processing unit in real time.

The processor 161 may communicate with a user through control interface [not shown] and display interface coupled to a display. The display may be, for example, a TFT LCD (Thin-Film-Transistor Liquid Crystal Display) or an OLED (Organic Light Emitting Diode) display, or other appropriate display technology. The display interface may comprise appropriate circuitry for driving the display to present graphical and other information to a user. The control interface may receive commands from a user and convert them for submission to the processor 161. In addition, an external interface may be provided in communication with the processor 161, so as to enable near area communication of system 100 with other devices. External interface may provide, for example, for wired communication in some implementations, or for wireless communication in other implementations, and multiple interfaces may also be used.

The computing unit 110 is shown as including the memory 162. The memory 162 may store the executable programming instructions 150. The executable instructions 150 may be stored or organized in any manner and at any level of abstraction, such as in connection with one or more applications, processes, routines, procedures, methods, functions, etc.

In one implementation, the memory 162 is a volatile memory unit or units. In another implementation, the memory 162 is a non-volatile memory unit or units. The memory 162 may also be another form of computer-readable medium, such as a magnetic or optical disk. In one implementation, a computer program product is tangibly embodied in an information carrier. The computer program product contains instructions that, when executed, perform one or more methods, such as those described above. The information carrier is a computer- or machine-readable medium, such as the memory, expansion memory, or memory on processor.

Expansion memory may also be provided and connected to device 110 through the expansion interface, which may include, for example, a SIMM (Single in Line Memory Module) card interface. Such expansion memory may provide extra storage space for device 110, or may also store applications or other information for the computing unit 110. Specifically, expansion memory may include instructions to carry out or supplement the processes described above, and may include secure information also. Thus, for example, expansion memory may be provided as a security module for the computing unit 110 and may be programmed with instructions that permit secure use of the computing unit 110. In addition, secure applications may be provided via the SIMM cards, along with additional information, such as placing identifying information on the SIMM card in a non-hackable manner.

The instructions stored in the memory 162 may be executed by one or more processors, such as a processor 161. The processor 102 may be coupled to one or more input/output (I/O) devices 165.

The storage device 166 is capable of providing mass storage for the computing unit 110. In one implementation, the storage device 166 may be or contain a computer-readable medium, such as a floppy disk device, a hard disk device, an optical disk device, a tape device, a flash memory or other similar solid state memory device, or an array of devices, including devices in a storage area network or other configurations. A computer program product can be tangibly embodied in an information carrier. The computer program product may also contain instructions that, when executed, perform one or more methods, such as those described above. The information carrier is a computer- or machine-readable medium, such as the memory 162, the storage device 166, or memory on processor 161.

In some embodiments, the I/O device(s) 165 may include one or more of a keyboard or keypad, a touchscreen or touch panel, a display screen, a microphone, a speaker, a mouse, a button, a remote control, a joystick, a printer, a telephone or mobile device (e.g., a smartphone), a sensor, etc. The I/O device(s) 165 may be configured to provide an interface to allow a user to interact with the computing unit 110 and/or the system 100.

The computing unit 100 may communicate wirelessly through communication interface, which may include digital signal processing circuitry where necessary. Communication interface may provide for communications under various modes or protocols, such as GSM voice calls, SMS, EMS, or MMS messaging, CDMA, TDMA, PDC, WCDMA, CDMA2000, or GPRS, among others. Such communication may occur, for example, through radio-frequency transceiver. In addition, short-range communication may occur, such as using a Bluetooth, Wi-Fi, or other such transceiver (not shown). In addition, GPS (Global Positioning System) receiver module may provide additional navigation- and location-related wireless data to system 100, which may be used as appropriate by applications running on the computing unit 110.

The computing unit 100 may also communicate audibly using audio codec, which may receive spoken information from a user and convert it to usable digital data set 114. Audio codec may likewise generate audible sound for a user, such as through a speaker, e.g., in a handset of the computing unit 100. Such sound may include sound from voice telephone calls, may include recorded sound (e.g., voice messages, music files, etc.) and may also include sound generated by applications operating on computing unit 100.

Additionally the computing unit 100 may include Universal Serial Bus (USB) flash drives. The USB flash drives may store operating systems and other applications. The USB flash drives can include input/output components, such as a wireless transmitter or USB connector that may be inserted into a USB port of another computing unit.

The system 100 is illustrative in figures. In some embodiments, one or more of the entities may be optional. In some embodiments, additional entities not shown may be included. For example, in some embodiments the system 100 may be associated with one or more networks. In some embodiments, the entities may be arranged or organized in a manner different from what is shown in FIG. 1.

Preferably, the computing unit 110 maybe a signal-connected with a GPS module for collecting a geographical location at a monitoring point, and the GPS module sends a geographical location signal to a processor; and the processor sends the geographical location signal to the master processor The wireless transceiver module further sends the received geographic location signal to the data receiving component 112.

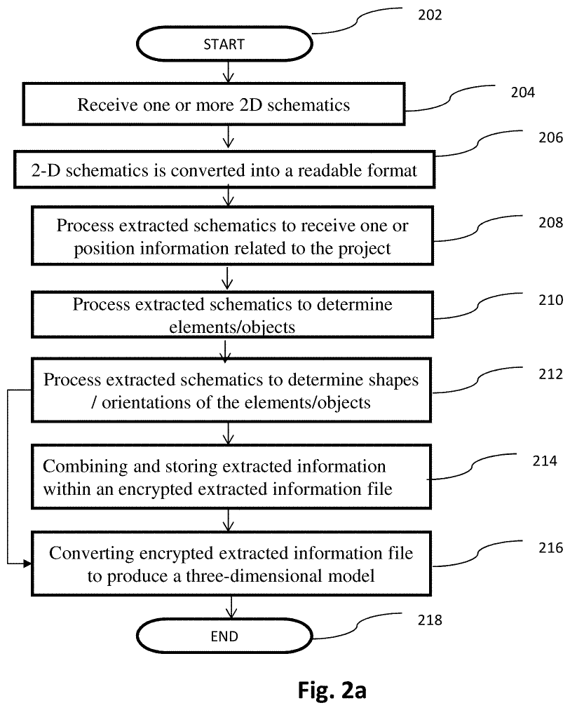

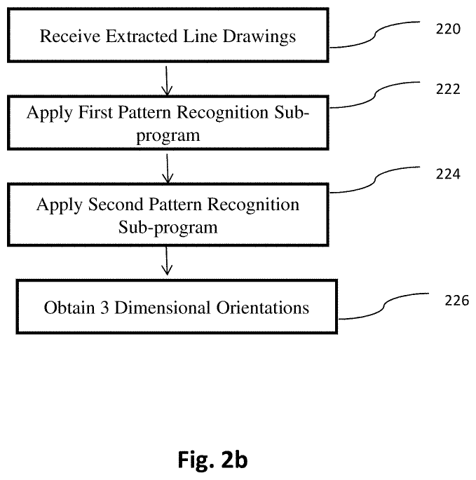

FIG. 2a illustrates a flow chart of a method of converting a set of two dimensional schematics, corresponding to a project, into a three-dimensional model according to the present invention. The method starts at step 202 and proceeds to step 204.

At step 204, one or more two dimensional schematics pertaining to a project, are received at the data receiving component 112 of the BIM Model of the computing unit 110. The 2-dimensional schematics includes images, lines and text information related to various project information such as project location information, element/structure information and shapes/orientation of the elements/objects and various other components of the project.

At step 206, the received 2-dimensional schematics is converted into a readable format as may be recognized by the system 100. Further, the 2-dimensional schematics may be assimilated using various filters to standardize the database and extract one or more information there from.

At step 208, the extracted schematics is processed to receive one or position information related to the project. Such an information may be mappable onto a map, and may be used to realize the location for display within the three-dimensional model. Preferably, the position data is extracted from the project data component of the two-dimensional schematics/drawings.

At step 210, the extracted schematics is processed to determine various elements and/or objects of the project. Such an information may further be classified into different kind of elements and/or objects. For example, the components may be classified in terms of utility of the architectural components, structural components, the MEP components, the interior components. Preferably, the position data is extracted from the text data component of the two-dimensional schematics/drawings.

At step 212, the extracted schematics is processed to determine shapes/orientations of the various elements and/or objects of the project. Such an information may further be supplemented with attributes such as dimension and other parameters relevant to the orientation. Preferably, the orientation data is extracted from the line drawings component of the two dimensional schematics/drawings.

Particularly as illustrated in FIG. 2b, the line drawings are received at step 220 which is then processed in accordance to a first pattern recognition sub-program at step 222 to receive a planar shape corresponding to the line drawing. Further, at step 224 the output from the first pattern recognition sub-program, i.e., the planar shape is further processed in accordance with a second pattern recognition sub-program to receive an orientation of the various elements and/or objects of the project at step 226.

At step 214, the each of the extracted components/information at steps 208, 210 and 212 are combined together and stored within an encrypted extracted information file 122. Thereafter, the method proceeds to step 216 where the encrypted extracted information file is converted to produce a three-dimensional model corresponding to the project. Such a model may further be visualized by a visualization component of the computing unit.

The process terminates at step 218. In an embodiment, the steps 206, 208, and 210 may be performed in any predetermined order, sequentially, as well as in parallel.

In some embodiments, the method proceeds directly from the step 212 to 216 where the extracted components/information at step 208, 210 and 212 are combined together and directly converted to produce a three-dimensional model corresponding to the project.

According to an embodiment, the system 100 is exemplified with a client architecture system in the form a web application. The web application includes a front-end user interface that can run off a standard web-browser on desktop environments, or a mobile based smartphone or tablet versions (for Android and iOS); and a backend server which can be a light weight workstation machine that will collect and process the data-sets received in accordance with one or more data sources including CAD libraries. In an embodiment, as illustrated, the front end user interface includes a login page. The logins for users are created and right management of the users are provisioned at the time of installation of the system to enable security of the data-sets, 3D models generated on the user interface of the mobile application. In some embodiments, one or more user roles may be provisioned by system administrator managing the system 100.

Henceforth, the system 100 of current disclosure provides capability for converting two dimensional schematics from all possible formats that may be available and/or provided by a designer, including CAD files, hand drawn sketches, digital images, but not limited thereto. Such a system also provides a capability of utilizing existing tools in addition to improvised BIM models to enable conversion to 3D model thereupon using the existing tools. Further, the constant updates and/or enhancements of the CAD libraries in combination with the AI sub-modules allows extension of capabilities and/or abilities of the model to new designs, components, products, shapes, orientations and so on.

Various connections are set forth between elements in the description and in the drawings (the contents of which are included in this disclosure by way of reference). These connections in general and, unless specified otherwise, may be direct or indirect and that this specification is not intended to be limiting in this respect. In this respect, a coupling between entities may refer to either a direct or an indirect connection.

Various embodiments of the invention have been disclosed. However, it should be apparent to those skilled in the art that modifications in addition to those described, are possible without departing from the inventive concepts herein. The embodiments, therefore, are not restrictive, except in the spirit of the disclosure. Moreover, in interpreting the disclosure, all terms should be understood in the broadest possible manner consistent with the context. In particular, the terms “comprises” and “comprising” should be interpreted as referring to elements, components, or steps, in a non-exclusive manner, indicating that the referenced elements, components, or steps may be present, or utilized, or combined with other elements, components, or steps that are not expressly referenced.

The disclosed methods and systems, as illustrated in the ongoing description or any of its components, may be embodied in the form of a computer system. Typical examples of a computer system include a general-purpose computer, a programmed microprocessor, a micro-controller, a peripheral integrated circuit element, and other devices, or arrangements of devices that are capable of implementing the steps that constitute the method of the disclosure.

The computer system comprises a computer, an input device, a display unit and the Internet. The computer further comprises a microprocessor. The microprocessor is connected to a communication bus. The computer also includes a memory. The memory may be Random Access Memory (RAM) or Read Only Memory (ROM). The computer system further comprises a storage device, which may be a hard-disk drive or a removable storage drive, such as, a floppy-disk drive, optical-disk drive, and the like. The storage device may also be a means for loading computer programs or other instructions into the computer system. The computer system also includes a communication unit. The communication unit allows the computer to connect to other databases and the Internet through an input/output (I/O) interface, allowing the transfer as well as reception of data from other sources. The communication unit may include a modem, an Ethernet card, or other similar devices, which enable the computer system to connect to databases and networks, such as, LAN, MAN, WAN, and the Internet. The computer system facilitates input from a user through input devices accessible to the system through an I/O interface.

In order to process input data, the computer system executes a set of instructions that are stored in one or more storage elements for example pre determined level of one or more parameters of gases as declared by government. The storage elements may also hold data or other information, as desired. The storage element may be in the form of an information source or a physical memory element present in the processing machine.

The programmable or computer-readable instructions may include various commands that instruct the processing machine to perform specific tasks, such as steps that constitute the method of the disclosure. The systems and methods described can also be implemented using only software programming or using only hardware or by a varying combination of the two techniques. The disclosure is independent of the programming language and the operating system used in the computers. The instructions for the disclosure can be written in all programming languages including, but not limited to, “C,” “C++,” “Visual C++,” Java, and “Visual Basic.” Further, the software may be in the form of a collection of separate programs, a program module containing a larger program or a portion of a program module, as discussed in the ongoing description. The software may also include modular programming in the form of object-oriented programming. The processing of input data by the processing machine may be in response to user commands, the results of previous processing, or from a request made by another processing machine. The disclosure can also be implemented in various operating systems and platforms including, but not limited to, “Unix,” “DOS,” “Android,” “Symbian.” and “Linux.”

The programmable instructions can be stored and transmitted on a computer-readable medium. The disclosure can also be embodied in a computer program product comprising a computer-readable medium, or with any product capable of implementing the above methods and systems, or the numerous possible variations thereof.

Various implementations of the systems and techniques described here can be realized in digital electronic circuitry, integrated circuitry, especially designed ASICs (application specific integrated circuits), computer hardware, firmware, software, and/or combinations thereof. These various implementations can include implementation in one or more computer programs that are executable and/or interpretable on a programmable system including at least one programmable processor, which may be special or general purpose, coupled to receive data and instructions from, and to transmit data and instructions to, a storage system, at least one input device, and at least one output device.

These computer programs (also known as programs, software, software applications or code) include machine instructions for a programmable processor, and can be implemented in a high-level procedural and/or object-oriented programming language, and/or in assembly/machine language. As used herein, the terms “machine-readable medium” and “computer-readable medium” refer to any computer program product, apparatus and/or device (e.g., magnetic discs, optical disks, memory, Programmable Logic Devices (PLDs)) used to provide machine instructions and/or data to a programmable processor.

To provide for interaction with a user, the systems and techniques described here can be implemented on a computer having a display device (e.g., a CRT (cathode ray tube) or LCD (liquid crystal display) monitor) for displaying information to the user and a keyboard and a pointing device (e.g., a mouse or a trackball) by which the user can provide input to the computer. Other kinds of devices can be used to provide for interaction with a user as well; for example, feedback provided to the user can be any form of sensory feedback (e.g., visual feedback, auditory feedback, or tactile feedback); and input from the user can be received in any form, including acoustic, speech, or tactile input.

A person having ordinary skills in the art will appreciate that the system, modules, and sub-modules have been illustrated and explained to serve as examples and should not be considered limiting in any manner. It will be further appreciated that the variants of the above disclosed system elements, or modules and other features and functions, or alternatives thereof, may be combined to create other different systems or applications.

The systems and techniques described here can be implemented in a computing system that includes a back end component (e.g., as a data server), or that includes a middleware component (e.g., an application server), or that includes a front end component (e.g., a client computer having a graphical user interface or a Web browser through which a user can interact with an implementation of the systems and techniques described here), or any combination of such back end, middleware, or front end components. The components of the system can be interconnected by any form or medium of digital data communication (e.g., a communication network). Examples of communication networks include a local area network (“LAN”), a wide area network (“WAN”), and the Internet.

The claims can encompass embodiments for hardware, software, or a combination thereof.

Although a few implementations have been described in detail above, other modifications are possible. Moreover, other mechanisms for performing the systems and methods described in this document may be used. In addition, the logic flows depicted in the figures may not require the particular order shown, or sequential order, to achieve desirable results. Other steps may be provided, or steps may be eliminated, from the described flows, and other components may be added to, or removed from, the described systems. Accordingly, other implementations are within the scope of the following claims.

1. A method for creating a three-dimensional (3D) object model using one or more two dimensional (2D) schematics, the method comprising:
obtaining the one or more 2D schematics onto a first application server, the server comprising a Building Information Modeling (BIM) program, the BIM program performing the following steps:
extracting location and/or position data for a project corresponding to the 2D schematics;
classifying objects disclosed therewithin the 2D schematics;
extracting a planar shape information for each of the classified objects wherein each of the planar shape information is utilized to determine a 3D shape of the corresponding object; and
combining an output of the foregoing extracting location and/or position data, classifying objects, and extracting a planar shape steps to provide a three-dimensional model corresponding to the 2D schematics,
the BIM program comprising an object library application utilizing an object library for performing the steps of extraction and classification wherein further the library application is adapted to encrypt the extracted and classified information and stored as an extracted information file of a predetermined format within the object library.

2. The method of claim 1, wherein the object library comprises a plurality of the 3D models corresponding to a plurality of extracted information files wherein further the library allows addition of new 3D object models corresponding to new extracted information files received from one or more second application server connected to the first application server.

3. The method of claim 1, wherein the 2D schematics comprising a combination of a text data, a plurality of line drawings and a project information data.

4. The method of claim 3, wherein the location and/or position data is extracted from the project information data.

5. The method of claim 3, wherein the objects are extracted from the text data.

6. The method of claim 3, wherein the 3D shapes of the objects are extracted from the line drawings.

7. The method of claim 6, wherein the 3D shapes are extracted using a first pattern recognition sub-program of the BIM program followed by a second pattern recognition sub-program applied onto an output of the first pattern recognition program.

8. The method of claim 1, wherein the predetermined format is a .CAP file format.

9. The method of claim 1, wherein BIM Program comprises a dimension sub-program configured to automatically determine dimensions for the 3D object model.

10. The method of claim 1, wherein the 2D drawings comprising a multi-floor building schematics, wherein further the BIM model outputs a 3D building model corresponding to the 2D drawings.

11. The method of claim 1, wherein 2D drawing is selected from the group consisting of a CAD Drawing, a hand-made sketch, and a digital image.

12. The method of claim 1, wherein the objects are selected from the group of building components consisting of architectural components, structural components, mechanical components, electrical components, plumbing components, firefighting components, interior components, and combinations thereof.

13. A non-transitory computer readable storage medium, having stored there on a computer program comprising instructions for implementing the method according to claim 1, when this program is executed by one or more processors.

14. A device comprising a computer for enhancing a digital model of a building, wherein said computer carries out the method according to claim 1.

15. The device according to claim 14, further comprises a memory for storing code for instructions of the method, at least one processor for executing said instructions, and an access to BIM 3D modeling Program.
